(19) United States
(12) Patent Application Publication
(10) Pub. No.: US 2023/0180572 A1
(43) Pub. Date: Jun. 8, 2023

(54) ELECTRONIC DEVICE

(71) Applicant: InnoLux Corporation, Miao-Li County (TW)

(72) Inventors: Hsiao-Lang LIN, Miao-Li County (TW); Tsung-Han TSAI, Miao-Li County (TW)

(21) Appl. No.: 18/051,909

(22) Filed: Nov. 2, 2022

(30) Foreign Application Priority Data
Dec. 8, 2021 (CN) 202111490012.3

(51) Int. Cl. H10K 59/38; H10K 59/80

(52) U.S. Cl. CPC H10K 59/38; H10K 59/8051; H10K 59/8052; H10K 59/8792; H10K 2102/302

(57) ABSTRACT

An electronic device is provided. The electronic device includes a first substrate, a second substrate, a first conductive element, an insulating layer, a first electronic element, and a medium structure. The second substrate is disposed opposite to the first substrate. The first conductive element is disposed on the first substrate. The insulating layer is disposed on the first conductive element and has a first via. The first electronic element is disposed on the insulating layer and electrically connected to the first conductive element through the first via. The medium structure is disposed between the first substrate and the second substrate. The medium structure has a first portion and a second portion. The first portion overlaps with the first via, and the second portion is adjacent to the first portion. In addition, the thickness of the first portion is greater than the thickness of the second portion.

### CROSS REFERENCE TO RELATED APPLICATIONS

This application claims the benefit of China Application No. 202111490012.3, filed Dec. 8, 2021, the entirety of which is incorporated by reference herein.

### BACKGROUND

### Technical Field

The present disclosure is related to an electronic device, and in particular it is related to an electronic device having a medium structure that can improve optical properties.

### Description of the Related Art

Electronic products including display panels, such as tablet computers, notebook computers, smartphones, displays, and televisions, have become indispensable necessities in modern society. With the flourishing development of various electronic products, consumers have high expectations for the quality, function, or price of these products.

In response to production costs and changes in application products, the process of manufacturing light-emitting elements of electronic devices (e.g., display panels) continues to evolve. In recent years, printing technology (e.g., ink-jet printing (IJP)) has also begun to be applied to the process of manufacturing light-emitting devices due to its characteristics of suitability for a large area, customized manufacturing and relatively simple process etc. However, the light-emitting elements manufactured using printing technology have problems such as poor thickness uniformity of the structure, which affects the optical performance.

As described above, existing electronic devices that include display panels still do not meet requirements in all respects. Therefore, researchers in this industry are currently seeking to develop a structural design that can further improve the performance of electronic devices.

### SUMMARY

In accordance with some embodiments of the present disclosure, an electronic device is provided. The electronic device includes a first substrate, a second substrate, a first conductive element, an insulating layer, a first electronic element, and a medium structure. The second substrate is disposed opposite to the first substrate. The first conductive element is disposed on the first substrate. The insulating layer is disposed on the first conductive element and has a first via. The first electronic element is disposed on the insulating layer and electrically connected to the first conductive element through the first via. The medium structure is disposed between the first substrate and the second substrate. The medium structure has a first portion and a second portion. The first portion overlaps with the first via, and the second portion is adjacent to the first portion. In addition, the thickness of the first portion is greater than the thickness of the second portion.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIG. 2 is a schematic diagram of a partial structure of an electronic device in accordance with some embodiments of the present disclosure;

FIG. 3A is a cross-sectional diagram of a partial structure of an electronic device in accordance with some embodiments of the present disclosure;

FIG. 3B is an enlarged schematic diagram of region R in FIG. 3A in accordance with some embodiments of the present disclosure;

FIG. 4 is a schematic diagram of a partial structure of an electronic device in accordance with some embodiments of the present disclosure;

FIG. 5 is a top-view diagram of a partial structure of an electronic device in accordance with some embodiments of the present disclosure;

FIG. 6 is a cross-sectional diagram of an electronic device corresponding to the section line Q-Q′ of FIG. 5 in accordance with some embodiments of the present disclosure;

FIG. 7A and FIG. 7B are diagrams showing the results of optical simulation of an electronic device in accordance with some embodiments of the present disclosure.

### DETAILED DESCRIPTION

An electronic device according to the present disclosure is described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as a part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “electrically coupled to” may include any direct or indirect electrical connection means.

In the following descriptions, terms “about” and “substantially” typically mean +/- 10% of the stated value, or typically +/- 5% of the stated value, or typically +/- 3% of the stated value, or typically +/- 2% of the stated value, or typically +/- 1% of the stated value or typically +/- 0.5% of the stated value. The expression “in a range from the first value to the second value” or “between the first value and the second value” means that the range includes the first value, the second value, and other values in between.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with the embodiments of the present disclosure, an electronic device having a medium structure with a specific structural design is provided, which can improve the optical performance (e.g., increase the luminous intensity), or the strength or reliability of the overall structure of the electronic device.

In accordance with the embodiments of the present disclosure, the electronic device may include a display device, a backlight device, a sensing device or a tiled device, but it is not limited thereto. The electronic device may be a bendable or flexible electronic device. The display device may be a non-self-luminous display device or a self-luminous display device. The sensing device may be a sensing device for sensing capacitance, light, heat or ultrasonic waves, but it is not limited thereto. The electronic device may include electronic components. The electronic components may include passive and active components, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LEDs), but they are not limited thereto. The tiled device may be, for example, a display tiled device or an antenna tiled device, but it is not limited thereto. It should be noted that, the electronic device may be any arrangement and combination of the foregoing, but it is not limited thereto. Hereinafter, the electronic device of the present disclosure will be described below by taking a display device as an example, but the present disclosure is not limited thereto.

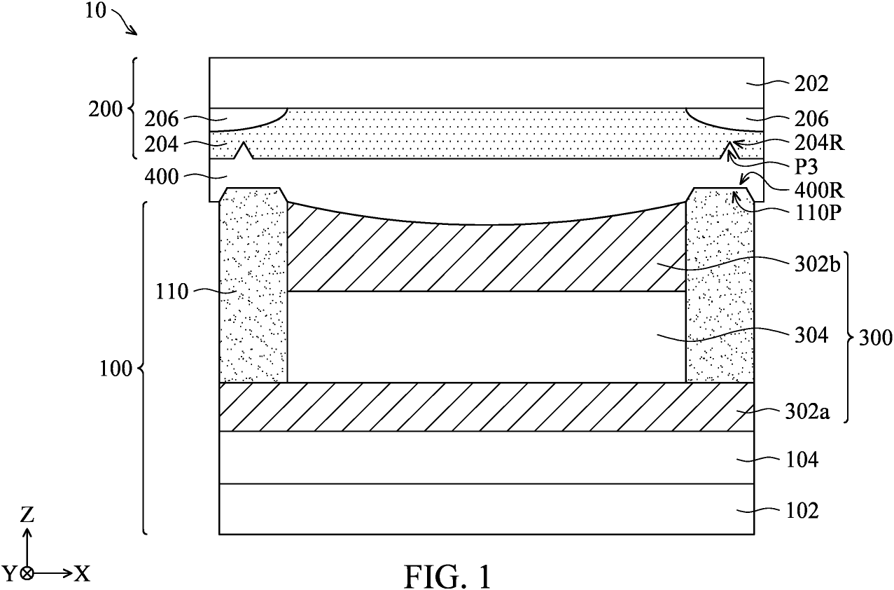

Refer to FIG. 1, which is a cross-sectional diagram of an electronic device 10 in accordance with some embodiments of the present disclosure. It should be understood that, some elements of the electronic device 10 are omitted in the drawings, and only some elements are schematically shown in the drawings for clarity. In accordance with some embodiments, additional features may be added to the electronic device 10 described below. In accordance with some other embodiments, some features of the electronic device 10 described below may be replaced or omitted.

The electronic device 10 may include a display substrate 100, a color filter substrate 200, and a medium structure 400 disposed between the display substrate 100 and the color filter substrate 200. The display substrate 100 may include a first substrate 102, a circuit layer 104 and an electronic element 300. The circuit layer 104 may be disposed on the first substrate 102, the electronic element 300 may be disposed on the circuit layer 104, and the electronic element 300 may be electrically connected to the circuit layer 104. Furthermore, the color filter substrate 200 may include a second substrate 202 and a color filter layer 204. The second substrate 202 may be disposed opposite to the first substrate 102. The color filter layer 204 may be disposed between the second substrate 202 and the medium structure 400.

The first substrate 102 and the second substrate 202 may serve as the bases of the display substrate 100 and the color filter substrate 200, respectively. The first substrate 102 and the second substrate 202 may include rigid substrates or flexible substrates. In accordance with some embodiments, the materials of the first substrate 102 and the second substrate 202 may include glass, quartz, sapphire, polyimide (PI), polycarbonate (PC), polyethylene terephthalate (PET), polydimethylsiloxane (PDMS), another suitable material, or a combination thereof, but it is not limited thereto. Moreover, the material of the first substrate 102 may be the same as or different from that of the second substrate 202.

The circuit layer 104 may include a driving circuit, and the driving circuit may include an active driving circuit and/or a passive driving circuit. In accordance with some embodiments, the driving circuit may include thin-film transistor (TFTs) (e.g., switching transistors, driving transistors, reset transistors, or other thin-film transistors), data lines, scan lines, conductive pads, dielectric layers, capacitors or other circuits, etc., but it is not limited thereto. In addition, the thin-film transistor may be a top gate thin-film transistor, a bottom gate thin-film transistor, or a dual gate (or double gate) thin-film transistor. The thin-film transistor may include at least one semiconductor layer, and the semiconductor layer may include, but is not limited to, amorphous silicon, low-temp polysilicon (LTPS), metal oxide, another suitable material, or a combination thereof. The metal oxide may include, but is not limited to, indium gallium zinc oxide (IGZO), indium zinc oxide (IZO), indium gallium zinc tin oxide (IGZTO), another suitable material, or a combination thereof.

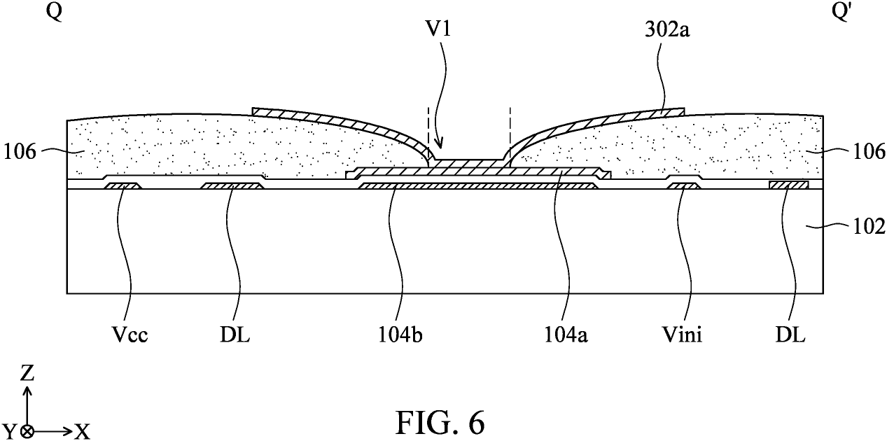

Specifically, in accordance with some embodiments, the circuit layer 104 may include a conductive element 104a (as shown in FIG. 6) and an insulating layer 106 (as shown in FIG. 6). The conductive element 104a and the insulating layer 106 may be the conductive element and insulating element in the driving circuit. The conductive element 104a may be disposed on the first substrate 102, and the insulating layer 106 may be disposed on the conductive element 104a and have a via V1 (as shown in FIG. 6). The electronic element 300 may be disposed on the insulating layer 106 and electrically connected to the conductive element 104a through the via V1 (not illustrated in FIG. 6). In accordance with some embodiments, the material of the insulating layer 106 may include, for example, silicon nitride (SiNx), silicon oxide (SiOx), silicon oxynitride (SiOxNy), epoxy resin, acrylic, bismaleimide, polyimide or a combination thereof, but it is not limited thereto. The detailed structure of the circuit layer 104 and the electronic element 300 will be further described below.

In accordance with the embodiments of the present disclosure, the electronic element 300 may be a light-emitting element. In accordance with some embodiments, the light-emitting element may include a light-emitting diode, which may include, for example, an organic light-emitting diode, a mini light-emitting diode, a micro light-emitting diode, or a quantum dot light-emitting diode (e.g., may be QLED or QDLED), another suitable light-emitting unit, or a combination thereof, but it is not limited thereto. In accordance with some embodiments, the electronic element 300 may be an organic light-emitting diode.

In accordance with some embodiments, the electronic element 300 may include an anode 302a, a cathode 302b, and a light-emitting layer 304, but the present disclosure is not limited thereto. The anode 302a may be disposed between the circuit layer 104 and the light-emitting layer 304. The anode 302a may be electrically connected to the conductive element 104a of the circuit layer 104 through the aforementioned via V1. The cathode 302b may be disposed between the light-emitting layer 304 and the medium structure 400. Furthermore, the light-emitting layer 304 may be disposed between the anode 302a and the cathode 302b. In accordance with some other embodiments, the cathode 302b may be at least partially disposed on a bank layer 110, but it is not limited thereto.

In accordance with some embodiments, the materials of the anode 302a, the cathode 302b, and the conductive element 104a may include metal conductive materials, transparent conductive materials, other suitable materials, or a combination thereof, but they are not limited thereto. The metal conductive material may include, for example, copper (Cu), aluminum (Al), indium (In), ruthenium (Ru), tin (Sn), gold (Au), platinum (Pt), molybdenum (Mo), zinc (Zn), silver (Ag), titanium (Ti), lead (Pb), nickel (Ni), neodymium (Nd), iridium (Ir), chromium (Cr), magnesium (Mg), palladium (Pd), lithium (Li), calcium (Ca), alloys of the foregoing metals, another suitable metal material, or a combination thereof, but it is not limited thereto. The transparent conductive material may include, for example, transparent conductive oxide (TCO), such as indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material, or a combination thereof, but it is not limited thereto. In addition, the anode 302a and the cathode 302b may have a single-layer or multi-layer structure.

In accordance with some embodiments, the light-emitting layer 304 may include a charge generation layer (not illustrated), a hole transport layer (not illustrated), an electron transport layer (not illustrated), an organic light-emitting layer (not illustrated) disposed between the hole transport layer and the charge generation layer and an additive material (not illustrated) for improving electron hole transport, but it is not limited thereto. In accordance with some embodiments, the light-emitting layer 304 of the electronic element 300 may be formed by an inkjet printing process, but the present disclosure is not limited thereto.

It should be understood that, according to different embodiments, the electronic element 300 may have another suitable structure, and the structure of the electronic element 300 is not limited to the structure of the aforementioned light-emitting element.

In addition, as shown in FIG. 1, in accordance with some embodiments, the electronic device 10 may include a bank layer 110. The bank layer 110 may be disposed on the circuit layer 104, for example, on the insulating layer 106 of the circuit layer 104. In accordance with some embodiments, the bank layer 110 may be disposed on the anode 302a of the electronic element 300, and the cathode 302b and the light-emitting layer 304 may be disposed between two adjacent bank layers 110.

In accordance with some embodiments, the bank layer 110 may be formed of a light-absorbing material, for example, a material with a light transmittance of less than 30%, which can reduce the occurrence of light mixing between adjacent electronic elements 300. In accordance with some embodiments, the bank layer 110 may be formed of a light-reflecting material, for example, a material with a reflectivity greater than 30%, which can increase the light output of the electronic element 300 and improve the light utilization rate. In accordance with some embodiments, the bank layer 110 may be formed of a transparent material, which can reduce the influence of the resistance of the material on the electronic element 300. Specifically, in accordance with some embodiments, the material of the bank layer 110 may include organic material, glass paste, another suitable material, or a combination thereof, but it is not limited thereto. The organic material may include, for example, epoxy resin, acrylic resin such as polymethylmethacrylate (PMMA), phenolic resin, polyamide resin, polyimide resin, unsaturated polyester resin, polyphenylene ether resin, polyphenylene sulfide resin, benzocyclobutene (BCB), another suitable material, or a combination thereof, but it is not limited thereto. In accordance with some embodiments, the material of the bank layer 110 may include black photoresist or white photoresist.

As mentioned above, the color filter substrate 200 may include the second substrate 202 and the color filter layer 204. The color filter layer 204 may be disposed between the second substrate 202 and the medium structure 400. The color filter layer 204 may filter or adjust the optical properties of light passing through it, e.g., pass light of a specific wavelength range. In accordance with some embodiments, the color filter layer 204 may include a red filter unit, a green filter unit, a blue filter unit, a white filter unit, or another color filter unit, but it is not limited thereto. According to different embodiments, the color filter layer 204 may have any suitable number or color of color filter units.

In accordance with some embodiments, the material of the color filter layer 204 may include a color photoresist. For example, the material of the color photoresist may include a polymer material and pigments and photosensitive materials dispersed therein. In accordance with some embodiments, the aforementioned polymer material may include epoxy resin, acrylic resin such as polymethylmethacrylate (PMMA), benzocyclobutene (BCB), another suitable material, or a combination thereof, but it is not limited thereto.

In accordance with some embodiments, the color filter substrate 200 may further include a light-shielding layer 206. The light-shielding layer 206 may be disposed on the second substrate 202 and located between the second substrate 202 and the color filter layer 204. Viewed from the light-emitting surface of the electronic device 10 (e.g., the X-Y plane in the drawing), the light-shielding layer 206 may have a plurality of openings, and the color filter layer 204 may overlap the openings of the light-shielding layer 206. Furthermore, in accordance with some embodiments, the light-shielding layer 206 may at least partially overlap with the bank layer 110 in a normal direction of the first substrate 102 (e.g., the Z direction in the drawings).

In accordance with some embodiments, the material of the light-shielding layer 206 may include black photoresist, black printing ink, black resin, metal, carbon black material, resin material, photosensitive material, another suitable material, or a combination thereof, but it is not limited thereto.

As described above, the medium structure 400 may be disposed between the first substrate 102 and the second substrate 202. As shown in FIG. 1, in accordance with some embodiments, the medium structure 400 may be disposed between the color filter layer 204 and the electronic element 300, and the medium structure 400 may abut against the bank layer 110. The medium structure 400 may have optical adjustment properties, protecting functions (e.g., waterproof and moisture-proof), or may serve as a snap-fit structure.

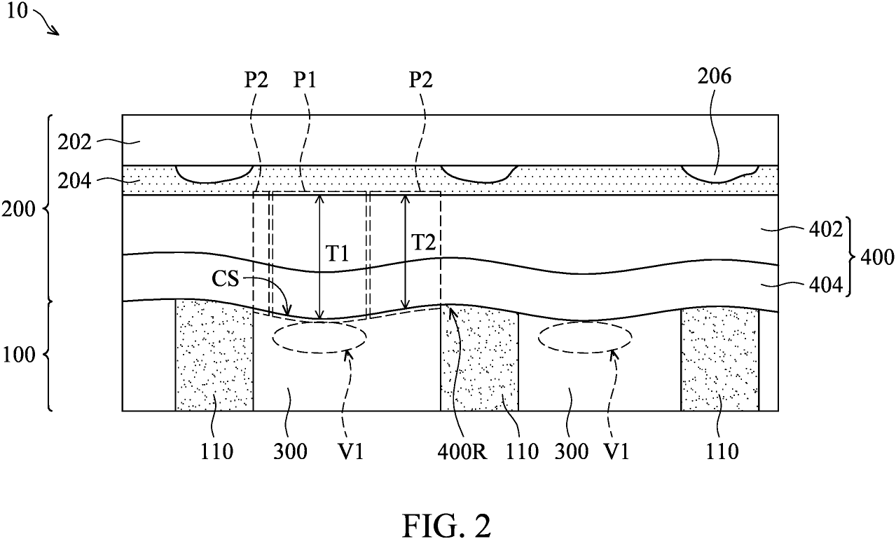

Specifically, refer to both FIG. 1 and FIG. 2. FIG. 2 is a schematic diagram of a partial structure of the electronic device 10 in accordance with some embodiments of the present disclosure. It should be understood that, for the sake of clarity, the display substrate 100 shown in FIG. 2 is presented from the top-view perspective, and the color filter substrate 200 is presented from the cross-sectional perspective, and the state where the display substrate 100 and the color filter substrate 200 are engaged is shown. In addition, FIG. 2 shows a region corresponding to two electronic elements 300 (e.g., two pixels) of the electronic device 10.

As shown in FIG. 2, the thickness of the medium structure 400 may be inconsistent. For example, the medium structure 400 corresponding to different regions of the display substrate 100 may have different thicknesses. Specifically, in a pixel area, the medium structure 400 may be divided into two parts. For example, the medium structure 400 may have a first portion P1 and a second portion P2. In the normal direction of the first substrate 102, the first portion P1 may overlap the via V1, the second portion P2 may be adjacent to the first portion P1, and a thickness T1 of the first portion P1 may be greater than a thickness T2 of the second portion P2. That is, the portion of the medium structure 400 overlapping the via V1 may have a relatively large thickness. As described above, the via V1 may electrically connect the anode 302a of the electronic element 300 with the conductive element 104a of the circuit layer 104. Furthermore, in accordance with some embodiments, the second portion P2 does not overlap the bank layer 110 in the normal direction of the first substrate 102. In accordance with some embodiments, the first portion P1 of the medium structure 400 may have a curved surface CS. Moreover, in accordance with some embodiments, the second portion P2 may have a flatter shape compared to the first portion P1.

In accordance with some embodiments, the thickness T1 of the first portion P1 may be between 9 µm and 21 µm (i.e. 9 µm ≤ thickness T1 ≤ 21 µm), for example, 10 µm, 11 µm,12 µm,13 µm, 14 µm,15 µm, 16 µm, 17 µm, 18 µm,19 µm or 20 µm, but it is not limited thereto. The thickness T2 of the second portion P2 may be between 8 µm and 18 µm (i.e. 8 µm ≤ thickness T2 ≤ 18 µm), for example, 9 µm, 10 µm, 11 µm, 12 µm, 13 µm,14 µm, 15 µm, 16 µm, or 17 µm,but it is not limited thereto.

In accordance with some embodiments of the present disclosure, the first portion P1 of the medium structure 400 refers to the area of the medium structure 400 having a radius of 10 micrometers (µm) defined with the maximum thickness as the center in a pixel area. In addition, the thickness T1 refers to the maximum thickness of the first portion P1 of the medium structure 400 in the normal direction of the first substrate 102 (e.g., the Z direction in the drawing) in a pixel area. The thickness T2 refers to the maximum thickness of the second portion P2 of the medium structure 400 in the normal direction of the first substrate 102 (e.g., the Z direction in the drawing) in a pixel area.

It should be understood that, in accordance with the embodiments of the present disclosure, an optical microscope (OM), a scanning electron microscope (SEM), a film thickness profiler (α-step), an ellipsometer, focused ion beam (FIB) microscope, transmission electron microscope (TEM), or other suitable methods can be used to measure the thickness, width or height of an element, or the distance or spacing between elements. Specifically, in accordance with some embodiments, a scanning electron microscope can be used to obtain a cross-sectional image including the element to be measured, and the thickness, width or height of the element, or the distance or spacing between elements in the image can be measured.

It should be noted that, in accordance with some embodiments, since the electronic element 300 is formed by an inkjet printing process, the ink has fluidity, so thicker ink will accumulate at the position corresponding to the via V1 and affect the luminous efficiency of the electronic element 300. However, the aforementioned structure design of the medium structure 400 having a relatively large thickness at the region overlapping with the via V1 can improve the effect of concentrating light and effectively improve the overall output light efficiency of the electronic element 300.

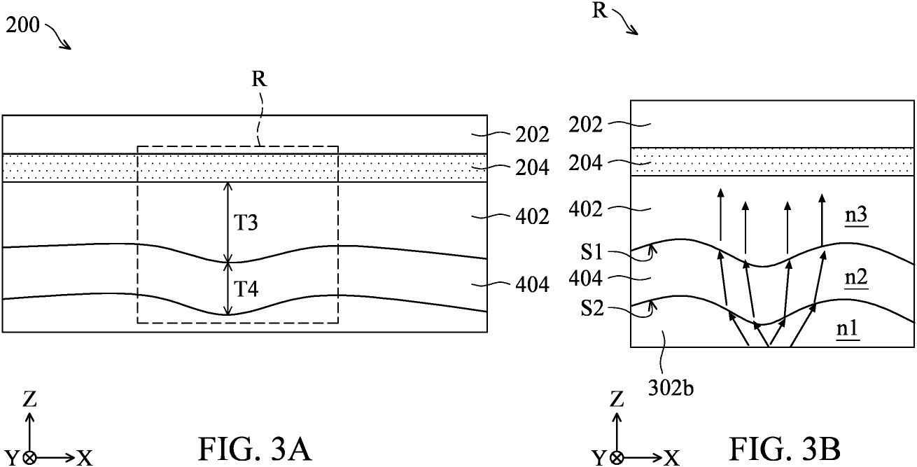

In addition, as shown in FIG. 2, in accordance with some embodiments, the medium structure 400 may have a multi-layer structure. For example, the medium structure 400 may have a first layer 402 and a second layer 404, and the first layer 402 may be disposed between the second substrate 202 and the second layer 404. Specifically, refer to both FIG. 3A and FIG. 3B. FIG. 3A is a cross-sectional diagram of a partial structure of the color filter substrate 200 of the electronic device 10 in accordance with some embodiments of the present disclosure, and FIG. 3B is an enlarged schematic diagram of region R in FIG. 3A.

In accordance with some embodiments, the first layer 402 of the medium structure 400 has a thickness T3, and the second layer 404 has a thickness T4. The thickness T3 of the first layer 402 may be greater than the thickness T4 of the second layer 404. Specifically, in accordance with some embodiments, the thickness T3 of the first layer 402 may be between 4 µm and 12 µm (i.e. 4 µm ≤ thickness T3 ≤ 12 µm), and the thickness T4 of the second layer 404 may be between 5 µm and 9 µm (i.e. 5 µm ≤ thickness T4 ≤ 9 µm).

In accordance with some embodiments of the present disclosure, the thickness T3 refers to the maximum thickness of the first layer 402 of the medium structure 400 in the normal direction of the first substrate 102 (e.g., the Z direction in the drawing) in a pixel area. The thickness T4 refers to the thickness of the second layer 404 of the dielectric structure 400 on the extension line where the first layer 402 has the maximum thickness. In accordance with some embodiments, the thickness T1 of the medium structure 400 may also be measured on the extension line where the first layer 402 has the maximum thickness, but it is not limited thereto.

Furthermore, as shown in FIG. 3B, in accordance with some embodiments, the first layer 402 of the medium structure 400 may have a first light-concentrating surface S1, and the second layer 404 may have a second light-concentrating surface S2. It should be noted that, the medium structure 400 having the multi-layer structure may have a plurality of light-concentrating surfaces, thereby further enhancing the light-converging effect and increasing the brightness of output light of the electronic element 300. Furthermore, the first layer 402 may have a refractive index n3, and the second layer 404 may have a refractive index n2. In accordance with some embodiments, the refractive index n3 of the first layer 402 and the refractive index n2 of the second layer 404 may be greater than a refractive index n1 of the cathode 302b. In accordance with some embodiments, the refractive index n2 of the second layer 404 may be smaller than the refractive index n3 of the first layer 402, but it is not limited thereto. Moreover, in accordance with some embodiments, the light transmittance of the medium structure 400 may be between 80% and 99%.

The term “transmittance” mentioned in the present disclosure refers to a percentage obtained by dividing the light intensity of the transmitted light measured after a light source penetrates an element, structure or material by the light intensity of the light source that does not penetrate the element, structure or material. The term “light intensity” mentioned in the present disclosure refers to the spectral integral value of the light source (the light source may include, for example, display light or ambient light). For example, when the light source is visible light, the light intensity is the spectral integral value within the wavelength range of 380 nm to 780 nm. The light transmittance of the medium structure 400 is the percentage of the visible light spectrum integral value measured after the light source penetrates the medium structure 400 divided by the visible light spectrum integral value measured when the light source does not penetrate the medium structure 400.

In accordance with some embodiments, the medium structure 400 may include an organic material layer. For example, the organic material may include polycarbonate (PC), polymethylmethacrylate (PMMA), polyethylene terephthalate (PET), polyethylene (PE), polyethersulfone (PES), polyimide (PI), polydimethylsiloxane (PDMS), another suitable organic material, or a combination thereof, but it is not limited thereto. In accordance with some embodiments, the medium structure 400 may include an adhesive layer. For example, the adhesive layer may include optical clear adhesive (OCA), optical clear resin (OCR), pressure sensitive adhesive (PSA), acrylic glue, acrylic resin, another suitable material, or a combination thereof, but it is not limited thereto. In accordance with some embodiments, the first layer 402 of the medium structure 400 may be an organic material layer, and the second layer 404 may be an adhesive layer, but the present disclosure is not limited thereto.

It should be understood that although the illustrated embodiment shows the medium structure 400 as a two-layer structure, according to different embodiments, the medium structure 400 may have other suitable numbers of layers, for example, 3 layers, 4 layers, 5 layers, 6 layers, 7 layers, 8 layers...etc. Moreover, the stacking order of the organic material layers and the adhesive layers in the medium structure 400 may also be adjusted as required.

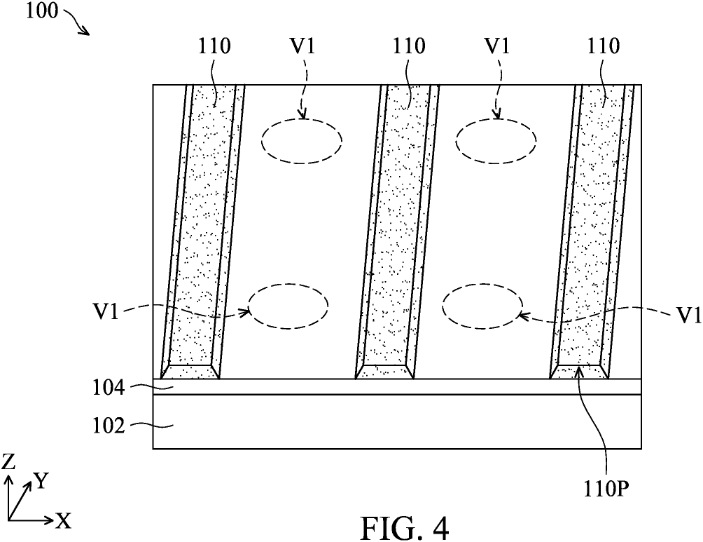

Next, refer to FIG. 1 and FIG. 4. FIG. 4 is a schematic diagram of a partial structure of the display substrate 100 of the electronic device 10 in accordance with some embodiments of the present disclosure. In accordance with some embodiments, the bank layer 110 may have a strip-shaped structure, and the bank layer 110 may have a convex profile 110P. Specifically, a top portion of the bank layer 110 may have a convex profile 110P. In accordance with some embodiments, the convex profile 110P may abut against the medium structure 400, and the medium structure 400 may partially surround the convex profile 110P.

In particular, the convex profile 110P may have the function of a tenon, which can assist the alignment of the display substrate 100 and the color filter substrate 200, and reduce the risk of displacement of the medium structure 400 (for example, the first portion P1 deviates without overlapping with the via V1, or the structural center of the medium structure 400 deviates from the structural center of the electronic element 300). In this way, the overall output light efficiency of the electronic element 300 can also be improved.

Furthermore, as shown in FIG. 1, in accordance with some embodiments, the medium structure 400 may have a groove 400R. The groove 400R may overlap with the bank layer 110 in the normal direction of the first substrate 102 (e.g., the Z direction in the drawing). Specifically, the groove 400R may be engaged with the convex profile 110P of the bank layer 110, so that the medium structure 400 and the bank layer 110 may be aligned and engaged more closely, thereby further improving the alignment accuracy of substrates of the electronic device 10. In accordance with some embodiments, the shapes of groove 400R and convex profile 110P may be complementary to each other.

In addition, referring to FIG. 1, in accordance with some embodiments, the color filter layer 204 may have a pitting structure 204R, and a third portion P3 of the medium structure 400 may be disposed in the pitting structure 204R. In accordance with some embodiments, in the normal direction of the first substrate 102 (e.g., the Z direction in the drawing), the pitting structure 204R of the color filter layer 204 may overlap with the light-shielding layer 206. In other words, the third portion P3 of the medium structure 400 may also overlap with the light-shielding layer 206.

In accordance with some embodiments, the third portion P3 of the medium structure 400 may be a convex structure. Specifically, the convex third portion P3 may be engaged with the pitting structure 204R, which can assist the alignment of the medium structure 400 and the color filter layer 204, thereby reducing the risk of displacement of the medium structure 400 or the color filter layer 204. Furthermore, in accordance with some embodiments, the shapes of the medium structure 400 and the color filter layer 204 may be complementary to each other.

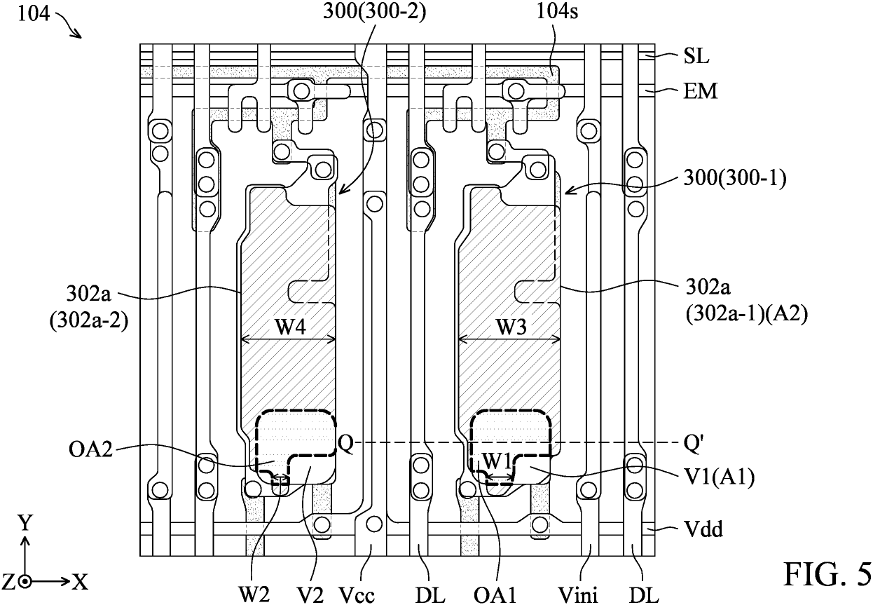

Next, refer to FIG. 5 and FIG. 6. FIG. 5 is a top-view diagram of a partial structure of the electronic device 10 in accordance with some embodiments of the present disclosure. FIG. 6 is a cross-sectional diagram of the electronic device 10 corresponding to the section line Q-Q′ in FIG. 5 in accordance with some embodiments of the present disclosure. Specifically, FIG. 5 shows a top-view diagram of the circuit layer 104 and the electronic element 300.

As shown in FIG. 5, the circuit layer 104 of the electronic device 10 may include a plurality of scan lines SL and a plurality of data lines DL. In accordance with some embodiments, the scan lines SL and the data lines DL may intersect to define a plurality of pixel areas, and the pixel areas may include a plurality of thin-film transistors and electronic elements 300. In accordance with some embodiments, the circuit layer 104 may further include a system voltage line Vcc, an operating voltage line Vdd, an initialization voltage line Vini, and a control signal line EM, but it is not limited thereto. The signal lines, voltage lines, etc. in the circuit layer 104 can work together to control and adjust the electronic element 300.

Specifically, after the scan line SL and the data line DL provide a signal to open the gate switch of the driving thin-film transistor, the current of the operating voltage line Vdd flows through the electronic element 300 to form a current loop, and the electronic element 300 will convert the electrical energy into light energy, so that the light-emitting layer 304 will output the light. Furthermore, the scan lines SL and the data lines DL may respectively extend along the X direction or the Y direction to form the circuit layer 104 in an intersection manner. The operating voltage line Vdd and the system voltage line Vcc may also respectively extend along the X direction or the Y direction to form the circuit layer 104 in an intersection manner. The operating voltage line Vdd may be arranged in the same direction as the scanning line SL, and the system voltage line Vcc may be arranged in the same direction as the data line DL, but the present disclosure is not limited thereto. Moreover, the initialization voltage line Vini may extend along the X direction or the Y direction to configure the circuit layer 104. For example, as shown in FIG. 5, the initialization voltage line Vini may be arranged along the Y direction, but it is not limited thereto. The arrangement direction of the initialization voltage line Vini may be the same as the arrangement direction of the data line DL or the system voltage line Vcc, but it is not limited thereto. In addition, the semiconductor layer 104s also may be disposed in the circuit layer 104. According to different embodiments, the circuit layer 104 may be designed as 4T2C (4 TFTs, 2 capacitors), 4T3C, 5T2C, 6T1C, 7T2C, 7T3C or 9T1C according to needs, but it is not limited thereto.

It should be understood that, for the sake of clarity, in the following description, reference numerals 300-1 and 300-2 are used to denote different electronic elements 300, and reference numerals 302a-1 and 302a-2 are used to denote different anodes 302a. The electronic element 300-1 and the electronic element 300-2 may be two adjacent electronic elements, and the anode 302a-1 and the anode 302a-2 may be the anodes of the electronic element 300-1 and the electronic element 300-2, respectively. Referring to FIG. 5 and FIG. 6, the electronic element 300-1 may include the anode 302a-1, and the anode 302a-1 may be electrically connected to the conductive element 104a through the via V1 penetrating the insulating layer 106. The via V1 has a first area A1, and the anode 302a-1 has a second area A2. In accordance with some embodiments, the ratio of the first area A1 to the second area A2 may be between 0.05 and 0.4 (i.e. 0.05 ≤ first area A1 / second area A2 ≤ 0.4), or between 0.15 and 0.3, for example, 0.2 or 0.25, but it is not limited thereto. In accordance with some embodiments, the anode 302a-2 of the electronic element 300-2 and a via V2 also may have a similar relationship of area ratio as that of the first area A1 and the second area A2, and thus will not be repeated herein.

In addition, although FIG. 6 does not illustrate the cross-sectional structure corresponding to the electronic element 300-2, it is understood that the electronic element 300-2 may be electrically connected to the circuit layer 104 in the same manner as the electronic element 300-1. Specifically, the anode 302a-2 of the electronic element 300-2 may be electrically connected to the conductive element in the circuit layer 104 through the via V2 in the insulating layer 106, and this conductive element and the aforementioned conductive element 104a may be the conductive layer disposed in the same layer. Furthermore, in accordance with some embodiments, the circuit layer 104 may include a conductive element 104b that is disposed below the conductive element 104a, and the conductive element 104b may serve as a common electrode.

In accordance with some embodiments, the electronic element 300-1 may emit red light or green light, and the electronic element 300-2 may emit blue light, but the present disclosure is not limited thereto. As shown in FIG. 5, the anode 302a-1 and the via V1 may have a first overlapping area OA (filled with dots for clarity), and the anode 302a-2 and the via V2 may have a second overlapping area OA2 (filled with dots for clarity). In accordance with some embodiments, a width W1 of the first overlapping area OA1 may be greater than a width W2 of the second overlapping area OA2. In accordance with some embodiments, the area of the first overlapping area OA1 may be larger than the area of the second overlapping area OA2. Furthermore, in accordance with some embodiments, a width W3 of the anode 302a-1 of the electronic element 300-1 may be greater than a width W4 of the anode 302a-2 of the electronic element 300-2.

In accordance with the embodiments of the present disclosure, the aforementioned width W1 and width W2 respectively refer to the minimum widths of the first overlapping area OA1 and second overlapping area OA2 in a direction parallel to an extending direction of the scan line SL (e.g., the X direction in the drawing). In addition, the aforementioned width W3 and width W4 respectively refer to the maximum widths of the anode 302a-1 and anode 302a-2 in a direction parallel to the extending direction of the scan line SL (e.g., the X direction in the drawing).

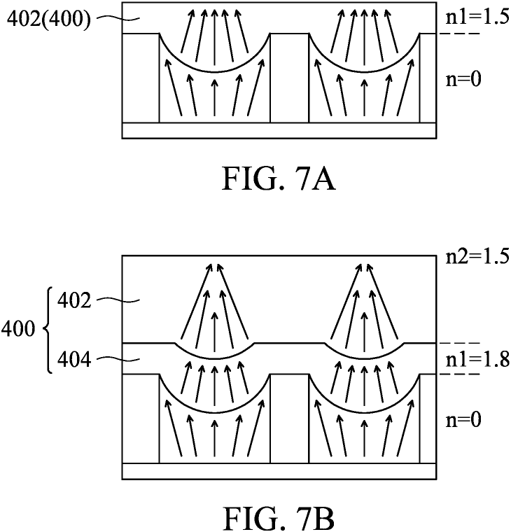

Next, refer to FIG. 7A and FIG. 7B. FIG. 7A and FIG. 7B are diagrams showing the results of optical simulation of the electronic device in accordance with some embodiments of the present disclosure. FIG. 7A is a diagram of the simulation result of the light reflection path of the medium structure 400 with a single-layer structure (the first layer 402). FIG. 7B is a diagram of the simulation result of the light reflection path of the medium structure 400 with a two-layer structure (the first layer 402 and the second layer 404).

As shown in FIG. 7A, the light rays emitted from the electronic elements originally diverged outwards, but after passing through the first layer 402, they converged inwardly. As shown in FIG. 7B, the light rays emitted from the electronic element firstly concentrated inward after passing through the first layer 402, and further concentrated inward after passing through the second layer 404, and the light-converging effect is more obvious. As mentioned above, the medium structure 400 having the multi-layer structure may have a plurality of light-concentrating surfaces, which can further enhance the light-converging effect and increase the brightness of output light of the electronic element.

To summarize the above, in accordance with the embodiments of the present disclosure, the provided electronic device includes the medium structure with a specific structural design, which has optical adjustment properties, protecting functions, or can serve as a snap-fit structure, thereby improving the luminous intensity, or the strength or reliability of the overall structure of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a first substrate;
a second substrate disposed opposite to the first substrate;
a first conductive element disposed on the first substrate;
an insulating layer disposed on the first conductive element and having a first via;
a first electronic element disposed on the insulating layer and electrically connected to the first conductive element through the first via; and
a medium structure disposed between the first substrate and the second substrate, and having a first portion and a second portion, wherein the first portion overlaps with the first via, and the second portion is adjacent to the first portion, and wherein a thickness of the first portion is greater than a thickness of the second portion.

2. The electronic device as claimed in claim 1, wherein the medium structure has a multi-layer structure.

3. The electronic device as claimed in claim 1, wherein a light transmittance of the medium structure is between 80% and 99%.

4. The electronic device as claimed in claim 1, further comprising a bank layer disposed on the insulating layer, wherein and the medium structure has a groove, and the groove overlaps with the bank layer.

5. The electronic device as claimed in claim 4, further comprising a light-shielding layer disposed on the second substrate, wherein the light-shielding layer at least partially overlaps with the bank layer in a normal direction of the first substrate.

6. The electronic device as claimed in claim 4, wherein the medium structure abuts against the bank layer.

7. The electronic device as claimed in claim 4, wherein the bank layer has a convex profile, the convex profile abuts against the medium structure, and the medium structure partially surrounds the convex profile.

8. The electronic device as claimed in claim 1, further comprising a color filter layer disposed between the second substrate and the medium structure.

9. The electronic device as claimed in claim 8, wherein the color filter layer has a pitting structure, and a third portion of the medium structure is disposed in the pitting structure.

10. The electronic device as claimed in claim 9, wherein the third portion has a convex structure.

11. The electronic device as claimed in claim 1, wherein the first electronic element comprises a first anode, the first anode is electrically connected to the first conductive element through the first via, the first via has a first area, the first anode has a second area, and a ratio of the first area to the second area is between 0.05 and 0.4.

12. The electronic device as claimed in claim 11, wherein the ratio of the first area to the second area is between 0.15 and 0.3.

13. The electronic device as claimed in claim 1, wherein the medium structure comprises a first layer and a second layer, the first layer is disposed between the second substrate and the second layer, and a thickness of the first layer is greater than a thickness of the second layer.

14. The electronic device as claimed in claim 13, wherein the first layer has a first refractive index, and the second layer has a second refractive index, and the second refractive index is smaller than the first refractive index.

15. The electronic device as claimed in claim 14, wherein the first electronic element comprises a cathode, and the cathode has a third refractive index, the first refractive index is greater than the third refractive index, and the second refractive index is greater than the third refractive index.

16. The electronic device as claimed in claim 1, wherein the first portion of the medium structure has a curved surface.

17. The electronic device as claimed in claim 1, further comprising a second conductive element disposed on the first substrate and a second electronic element disposed on the insulating layer, wherein the second electronic element is electrically connected to the second conductive element through a second via, and the first electronic element emits red light or green light, and the second electronic element emits blue light.

18. The electronic device as claimed in claim 17, wherein the first electronic element comprises a first anode, the first anode is electrically connected to the first anode through the first via, and the second electronic element comprises a second anode, the second anode is electrically connected to the second conductive element through the second via, the first anode and the first via have a first overlapping area, the second anode and the second via have a second overlapping area, and wherein a width of the first overlapping area is greater than a width of the second overlapping area.

19. The electronic device as claimed in claim 17, wherein the first electronic element comprises a first anode, the first anode is electrically connected to the first anode through the first via, and the second electronic element comprises a second anode, the second anode is electrically connected to the second conductive element through the second via, the first anode and the first via have a first overlapping area, the second anode and the second via have a second overlapping area, and wherein an area of the first overlapping area is larger than an area of the second overlapping area.

20. The electronic device as claimed in claim 17, wherein the first electronic element comprises a first anode, the first anode is electrically connected to the first conductive element, the second electronic element comprises a second anode, and the second anode is electrically connected to the second conductive element, and wherein a width of the first anode is greater than a width of the second anode.
